(19) United States
(12) Patent Application Publication
(10) Pub. No.: US 2007/0006056 A1
(43) Pub. Date: Jan. 4, 2007

(54) Method and apparatus for enabling multipoint bus access

(75) Inventors: Thomas Lehner, Roth (DE); Hans-Joachim Goetz, Nuernberg (DE)

Correspondence Address: PATTERSON & SHERIDAN, LLP/;LUCENT TECHNOLOGIES, INC, 595 SHREWSBURY AVENUE, SHREWSBURY, NJ, 07702, US

(73) Assignee: Lucent Technologies Inc.

(21) Appl. No.: 11/172,002

(22) Filed: Jun. 30, 2005

(51) Int. Cl. G01R 31/28

(52) U.S. Cl. 714/727

(57) ABSTRACT

The invention includes a method and apparatus for enabling multipoint bus access. In one example, the open ring-architecture bus includes a boundary scan bus including a plurality of bus access points adapted for interfacing with a plurality of circuit packs, a first termination circuit coupled to a first end of the bus, and a second termination circuit coupled to a second end of the bus. The first termination circuit and second termination circuit are adapted for terminating signaling on the boundary scan bus. The open-ring architecture bus provides a master circuit pack a multipoint access capability such that the master circuit pack may be disposed at any of the plurality of bus access points. In one example, signaling includes signaling operable for performing hierarchical system testing, including boundary scan testing. In another example, signaling includes upgrade signaling operable for performing firmware upgrades, software upgrades, and like circuit pack upgrades.

### FIELD OF THE INVENTION

The invention relates to the field of communication buses and, more specifically, to boundary scan buses.

### BACKGROUND OF THE INVENTION

The IEEE 1149.5 standard describes a serial, backplane, test and maintenance bus (MTM-Bus) used for integrating modules into testable and maintainable subsystems/systems. The IEEE 1149.5 standard is used in conjunction with the IEEE 1149.1 standard within a system/subsystem to provide hierarchical testing capabilities. In this case, the MTM-Bus is designed as a hierarchical boundary scan bus including at least four (and, optionally, five) boundary scan lines for hierarchical boundary scan testing. In existing backplanes (e.g., backplanes used in telecommunications systems), the common bus architecture includes a common bus, a master circuit pack (e.g., a control (CTL) card which includes the boundary scan master device), and several slave circuit packs which access the common bus using addressable scan ports (ASPs).

The common bus architecture of existing systems is designed with the master circuit pack at one end of the common bus architecture (i.e., the master circuit pack terminates the common bus at the source side) and a bus termination which terminates the boundary scan lines at the other end of the common bus (i.e., on the backplane). Unfortunately, in such common bus architectures, the boundary scan master circuit pack may only be placed at one end of the common bus. In other words, using this existing design for terminating a hierarchical boundary scan bus at the system level, it is not possible for the boundary scan master circuit pack to be placed in each slot of a telecommunication system since the termination at the slot formerly used by the boundary scan master circuit pack is not equipped (i.e., termination is missing).

### SUMMARY OF THE INVENTION

Various deficiencies in the prior art are addressed through the invention of a method and apparatus for enabling multipoint bus access. In one embodiment, the open ring-architecture bus comprises a boundary scan bus including a plurality of bus access points adapted for interfacing with a plurality of circuit packs, a first termination circuit coupled to a first end of the bus, and a second termination circuit coupled to a second end of the bus. The first termination circuit and second termination circuit are adapted for terminating signaling on the boundary scan bus. The open-ring architecture bus provides a master circuit pack a multipoint access capability such that the master circuit pack may be disposed at any of the plurality of bus access points for controlling signaling on the boundary scan bus In one embodiment, signaling includes signaling operable for performing hierarchical system testing. In one further embodiment, signaling includes signaling for performing boundary scan testing. In another embodiment, signaling includes upgrade signaling operable for performing firmware upgrades, software upgrades, and like circuit pack upgrades.

### BRIEF DESCRIPTION OF THE DRAWINGS

The teachings of the present invention can be readily understood by considering the following detailed description in conjunction with the accompanying drawings, in which:

FIG. 1 depicts a high-level block diagram of an open-ring architecture bus;

FIG. 2 depicts a physical representation of a telecommunications system including an open-ring architecture bus;

FIG. 3 depicts a logical representation of the telecommunication system of FIG. 2 including the open-ring architecture bus;

FIG. 4 depicts a flow diagram of a method according to one embodiment of the invention; and

FIG. 5 depicts a high-level block diagram of a general purpose computer suitable for use in performing the functions described herein To facilitate understanding, identical reference numerals have been used, where possible, to designate identical elements that are common to the figures.

### DETAILED DESCRIPTION OF THE INVENTION

The invention is discussed in the context of a telecommunication system comprising hierarchical boundary scan capabilities; however, the present invention readily be applied to other systems. In general, the present invention comprises an open-ring architecture bus operable for providing a multipoint access capability for a master circuit pack. Using the open-ring architecture bus, a master circuit packet may be disposed at any bus access point adapted for interfacing with the bus. As such, according to the present invention, a master circuit pack may control slave circuits packs from any position on the open-ring architecture bus. In one embodiment, the open-ring architecture bus is operable for supporting signaling between a master circuit pack and at least one slave circuit pack irrespective of the respective access points of the master circuit pack and the at least one slave circuit pack.

In one embodiment, the open-ring architecture bus is operable for supporting hierarchical testing capabilities. In one such embodiment, the open-ring architecture bus is operable for supporting boundary scan testing. In one such embodiment, in which the open-ring architecture bus comprises a portion of a telecommunications system, the master circuit pack multipoint access capability enables use of each slot for controlling boundary scan testing. In one further embodiment, boundary scan test access is supported irrespective of the configuration in which the slots are equipped with circuit packs. As such, the present invention reduces the costs for boundary scan access hardware, firmware, software, services, and the like. Furthermore, the present invention enables boundary scan testing to be offered as a customer usable feature.

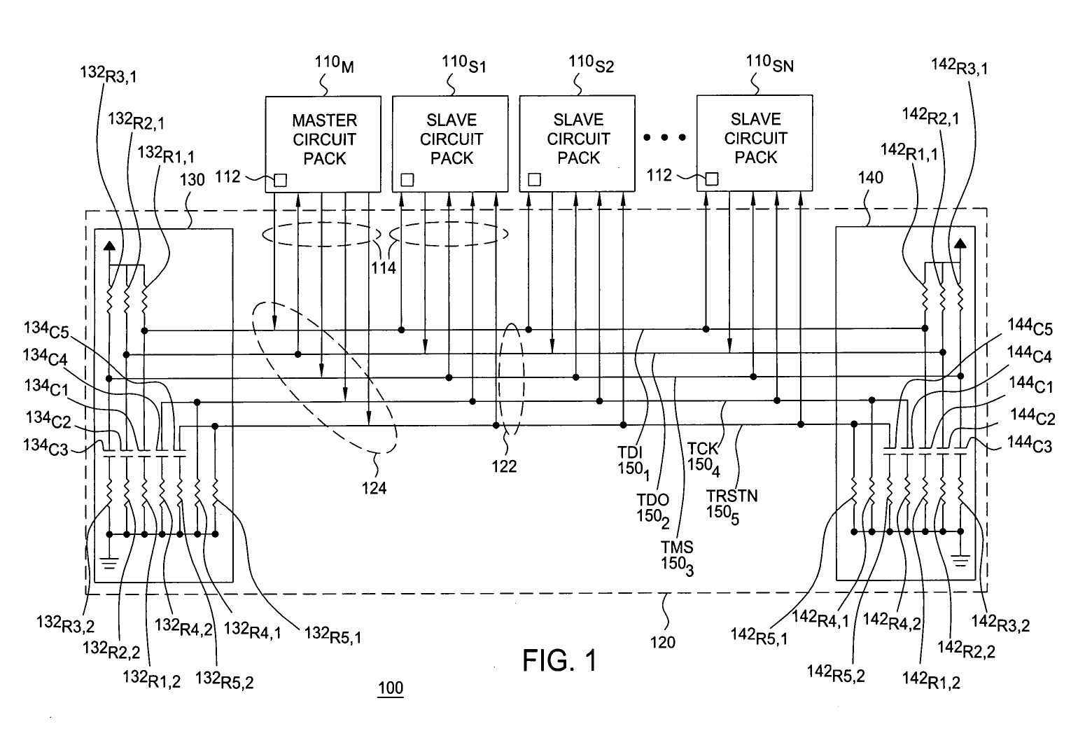

FIG. 1 depicts a high-level block diagram of an open-ring architecture bus. In general, FIG. 1 depicts a high-level block diagram of a boundary scan system comprising an open-ring architecture bus. Specifically, boundary scan system 100 of FIG. 1 comprises a plurality of circuit packs (CPs) 110₁-110_{N} (collectively, CPs 110) and an open-ring architecture bus (ORAB) 120. As depicted in FIG. 1, ORAB 120 comprises a bus 122, a plurality of bus access points (BAPs) 124 (collectively, BAPs 124) associated with bus 122, a first termination circuit (FTC) 130, and a second termination circuit (STC) 140. The CPs 110 communicate with ORAB 120 using respective pluralities of bus access lines (BALs) 114 (collectively, BALs 114). In one embodiment, BAPs 124 are adapted for enabling CPs 110 to interface with ORAB 120 using BALs 114.

In one embodiment, bus 122 comprises a boundary scan bus operable for supporting various signaling, including boundary scan test signaling. As depicted in FIG. 1, bus 122 comprises a first end, which is terminated by FTC 130. Similarly, as depicted in FIG. 1, bus 122 comprises a second end, which is terminated by STC 140. In one embodiment, ORAB 120 is adapted for supporting signaling between CPs 110. In one such embodiment, ORAB 120 is adapted for supporting boundary scan signaling. For example, as depicted in FIG. 1, CPs 110, ORAB 120, and BALs 122 are operable for supporting a plurality of boundary scan signals (BSSs) 150₁-150₅ (collectively, BSSs 150).

As depicted in FIG. 1, CPs 110 comprise a master circuit pack (MCP) 110_{M} and a plurality of slave circuit packs (SCPs) 110_{S1}- 110_{SN} (collectively, SCPs 110_{S}). Although depicted as accessing ORAB 120 from specific access points (illustratively, BAPs 124), as described herein, the ORAB 120 provides MCP 110_{M} multipoint access capability enabling MCP 110_{M} to access ORAB 120 from any bus access point associated with ORAB 120. As depicted in FIG. 1, BSSs 150 comprise a test data input (TDI) signal 150₁ (denoted TDI 150₁), a test data output (TDO) signal 150₂ (denoted TDO 150₂), a test mode select (TMS) signal 150₃ (denoted TMS 150₃), a test clock (TCK) signal 150₄ (denoted TCK 150₄), and, optionally, a test rest (TRST) signal 150₅ (denoted TRST 150₅).

As depicted in FIG. 1, MCP 110_{M} outputs TDI 120₁ TMS 120₃ TCK 120₄ and TRST 120₅ to ORAB 120. The SCPs 110_{S} input TDI 120₁ TMS 120₃ TCK 120₄ and TRST 120₅ from ORAB 120. The SCPs 110_{S} output TDO 120₂ to ORAB 120. The MCP 110_{M} inputs TDO 120₂ from ORAB 120. As depicted in FIG. 1, BSSs 150 are transported between CPs 110, as well as to FTC 130 and STC 140, over CB 124. As depicted in FIG. 1, FTC 130 terminates a first end of ORAB 120 and STC 140 terminates a second end of ORAB 120 in a manner for providing MCP 110_{M} multipoint access capabilities. As such, although depicted as interfacing with ORAB 120 from a particular bus access point, MCP 110_{M} may be disposed at any BAP 124 associated with the ORAB 120.

In one embodiment, the CPs 110 comprise a respective plurality of addressable scan port (ASP) modules 112 (collectively, ASP modules 112). In general, an ASP module comprises a plurality of address pins. The master circuit pack addresses each slave circuit pack connected to the open-ring architecture bus. In one embodiment, addressing of slave circuit packs is performed using a shadow protocol. Using at least one protocol (e.g., a shadow protocol for addressing for boundary scan testing), a specific card may be assigned a unique address. In one embodiment, the address of the card is defined by the address pins of the ASP module.

As depicted in FIG. 1, FTC 130 is adapted for terminating signaling on a first end of ORAB 120 (i.e., signaling received via bus 122). Similarly, STC 140 is adapted for terminating signaling on a second end of ORAB 120 (i.e., signaling received via bus 122). Although depicted as circuits adapted for terminating signaling on a boundary scan bus, in one embodiment, FTC 130 and STC 140 may be adapted for terminating signaling on other bus types supporting different signaling. Although depicted as distinct circuit modules, in one embodiment, FTC 130 and STC 140 comprise respective portions of one module adapted for interfacing with ORAB 120. In this embodiment, FTC 130 and STC 140 comprise distinct portions of the module (i.e., no direct connection between FTC 130 and STC 140).

The FTC 130 comprises a plurality of resistors 132 (collectively, resistors 132) and a plurality of capacitors 134 (collectively, capacitors 134) operable for terminating at least a portion of the signals on CB 124. As depicted in FIG. 1, FTC 130 terminates at least a portion of the BSSs 150. The TDI 150₁ is terminated by resistors 132_{R1,1} and 132_{R1,2} and capacitor 134_{C1}. The TDO 150₂ is terminated by resistors 132_{R2,1} and 132_{R2,2} and capacitor 134_{C2}. The TMS 150₃ is terminated by resistors 132_{R3,1} and 132_{R3,2} and capacitor 134_{C3}. The TCK 150₄ is terminated by resistors 132_{R4,1} and 132_{R4,2} and capacitor 134_{C4}. The TRST 150₅ is terminated by resistors 132_{R5,1} and 132_{R5,2} and capacitor 134_{C5}.

The resistors 132_{R1,1}, 132_{R2,1}, and 132_{R3,1} are coupled to a common voltage source. The resistors 132_{R1,2}, 132_{R2,2}, 132_{R3,2}, 132_{R4,1}, 132_{R4,2}, 132_{R5,1} and 132_{R5,2} are coupled to a common ground. Furthermore, resistor 132_{R1,1} is coupled to one terminal of capacitor 134_{C1} and resistor 132_{R1,2} is coupled to the other terminal of capacitor 134_{C1}. The resistor 132_{R2,1} is coupled to one terminal of capacitor 134_{C2} and resistor 132_{R2,2} is coupled to the other terminal of capacitor 134_{C2}. The resistor 132_{R3,1} is coupled to one terminal of capacitor 134_{C3} and resistor 132_{R3,2} is coupled to the other terminal of capacitor 134_{C3}. The resistor 132_{R4,1} is coupled to one terminal of capacitor 134_{C4} and resistor 132_{R4,2} is coupled to the other terminal of capacitor 134_{C4}. The resistor 132_{R5,1} is coupled to one terminal of capacitor 134_{C5} and resistor 132_{R5,2} is coupled to the other terminal of capacitor 134_{C5}.

Similarly, STC 140 comprises a plurality of resistors 142 (collectively, resistors 142) and a plurality of capacitors 144 (collectively, capacitors 134) operable for terminating at least a portion of the signals on CB 124. As depicted in FIG. 1, STC 140 terminates at least a portion of the BSSs 150. The TDI 150₁ is terminated by resistors 142_{R1,1} and 142_{R1,2} and capacitor 144_{C1}. The TDO 150₂ is terminated by resistors 142_{R2,1} and 142_{R2,2} and capacitor 144_{C2}. The TMS 150₃ is terminated by resistors 142_{R3,1} and 142_{R3,2} and capacitor 144_{C3}. The TCK 150₄ is terminated by resistors 142_{R4,1} and 142_{R4,2} and capacitor 144_{C4}. The TRST 150₅ is terminated by resistors 142_{R5,1} and 142_{R5,2} and capacitor 144_{C5}.

The resistors 142_{R1,1}, 142_{R2,1}, and 142_{R3,1} are coupled to a common voltage source. The resistors 142_{R1,2}, 142_{R2,2}, 142_{R3,2}, 142_{R4,1}, 142_{R4,2}, 142_{R5,1} and 142_{R5,2} are coupled to a common ground. Furthermore, resistor 142_{R1,1} is coupled to one terminal of capacitor 144_{C1} and resistor 142_{R1,2} is coupled to the other terminal of capacitor 144_{C1}. The resistor 142_{R2,1} is coupled to one terminal of capacitor 144_{C2} and resistor 142_{R2,2} is coupled to the other terminal of capacitor 144_{C2}. The resistor 142_{R3,1} is coupled to one terminal of capacitor 144_{C3} and resistor 142_{R3,2} is coupled to the other terminal of capacitor 144_{C3}. The resistor 142_{R4,1} is coupled to one terminal of capacitor 144_{C4} and resistor 142_{R4,2} is coupled to the other terminal of capacitor 144_{C4}. The resistor 142_{R5,1} is coupled to one terminal of capacitor 144_{C5} and resistor 142_{R5,2} is coupled to the other terminal of capacitor 144_{C5}.

Although depicted as comprising specific numbers of resistors and capacitors, those skilled in the art will appreciate that FTC 130 and STC 140 may be implemented using fewer or more resistors and capacitors. Similarly, the resistors and capacitors may be arranged in various other configurations. Similarly, other circuitry may be utilized for terminating signaling on the open-ring architecture bus of the present invention. Furthermore, although described herein with respect to boundary scan signaling operable for performing boundary scan test capabilities, in one embodiment, the open-ring architecture bus of the present invention is operable for supporting various other signaling between circuit packs.

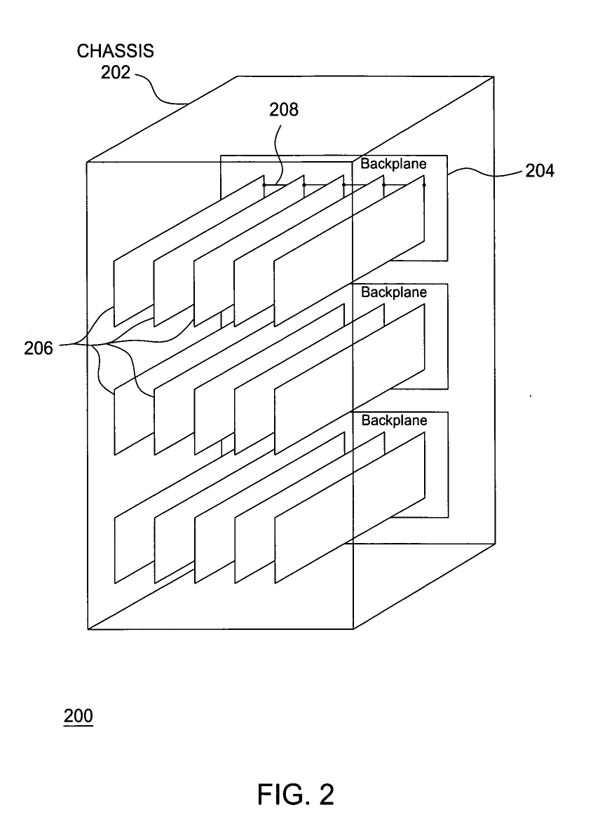

FIG. 2 depicts a physical representation of a telecommunication system including an open-ring architecture bus. Specifically, communication system 200 of FIG. 2 comprises a chassis 202. The chassis 202 comprises a plurality of shelves, where each shelf comprises a respective plurality of circuit packs (CPs) 204 (collectively, CPs 204) connected to a backplane 206. A bus 208 interconnects CPs 204 such that signals may be exchanged between CPs 204. In one embodiment, bus 208 comprises an open-ring architecture bus. Thus, in one embodiment, CPs 204 of FIG. 2 correspond to CPs 110 of FIG. 1, and bus 208 of FIG. 2 corresponds to ORAB 120 of FIG. 1. Although depicted as enabling communication between CPs associated with a single shelf, in one embodiment, an ORAB is adapted for enabling communication between CPs on different shelves, between CPs on different chassis, and the like.

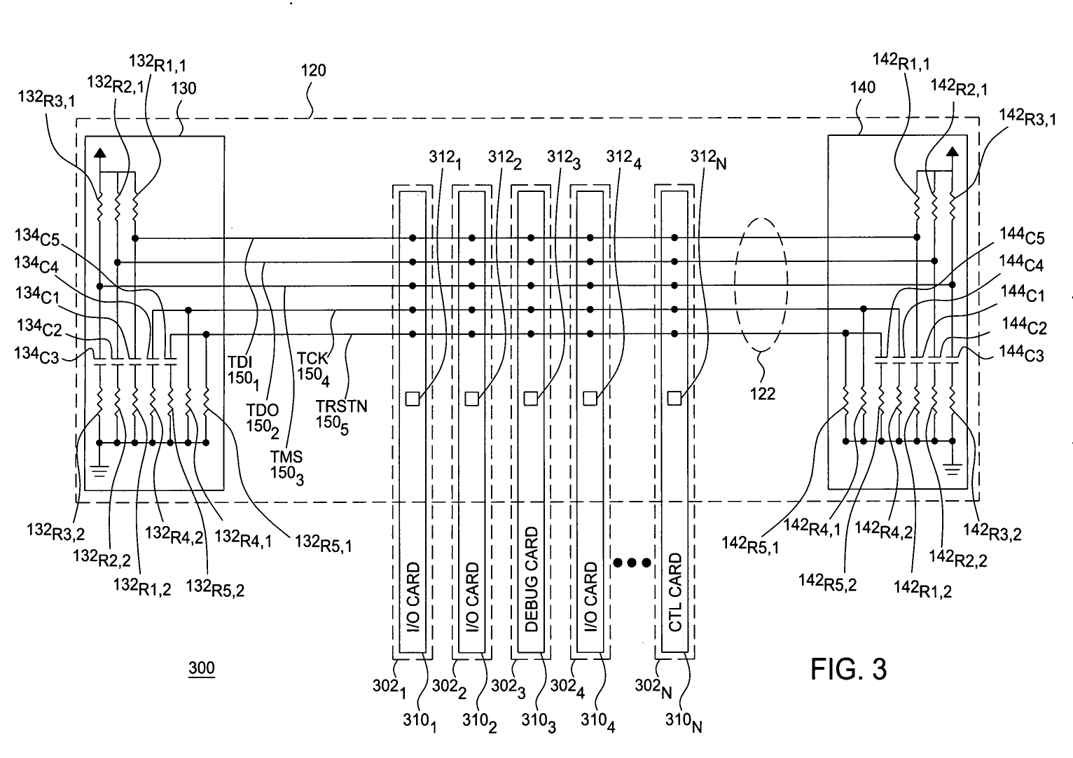

In one embodiment, CPs 204 may comprise control (CTL) cards, input-output (I/O) cards (e.g., cards supporting network traffic), testing cards (e.g., debug (DEBUG) cards), and like telecommunications cards. In one embodiment, at least one of the first termination circuit and the second termination circuit of the open-ring architecture bus is implemented as at least a portion of at least one of the CPs 204. In one embodiment, at least one of the first termination circuit and the second termination circuit of the open-ring architecture bus is implemented as at least a portion of the backplane 206, a portion of a module coupled to backplane 206, and the like. A rear view of one of the shelves of chassis 202 is described herein with respect to FIG. 3.

FIG. 3 depicts a logical representation of a rear view of a backplane associated with a shelf of the telecommunication system of FIG. 2 including an open-ring architecture bus. Specifically, shelf 300 of FIG. 3 comprises bus 122, BAPs 124, FTC 130, STC 140, and a plurality of cards 310₁-310_{N} (collectively, cards 310). The cards 310 are located in a respective plurality of slots 302₁-302_{N} (collectively, slots 302). As depicted in FIG. 3, card 310₁ comprises an I/O card, card 310₂ comprises an I/O card, card 310₃ comprises a debug (DEBUG) card, card 310₄ comprises an I/O card, and card 310_{N} comprises a CTL card. Although depicted as comprising specific cards 310, in one embodiment, at least a portion of the slots 302 are adapted such that any card type may be disposed within slots 302.

As depicted in FIG. 3, cards 310 access bus 122 of ORAB. In one embodiment, slots 302 are adapted for providing BAPs 124 from which a circuit pack may access ORAB 120. In one embodiment, cards 310 comprise a respective plurality of addressable scan port (ASP) modules 312₁-312_{N} (collectively, ASP modules 312). In general, an ASP module comprises a plurality of address pins. In one embodiment, identifications pins, which are unique for each slot, are provided to the address pins of the ASP of the card located in that slot. As such, a card is assigned an address based upon the slot in which the card is inserted. As described herein, a master circuit pack addresses each slave circuit pack connected to the open-ring architecture bus.

In one embodiment, addressing of slave circuit packs (i.e., non-master circuit packs) is performed using at least one protocol (e.g., a shadow protocol for addressing for boundary scan testing), a specific card may be assigned a unique address. In one embodiment, the address of a card is defined by the address pins of the ASP. For example, in one embodiment, in which card 310_{N} (i.e., CTL card) comprises the master circuit pack, CTL card 310_{N} addresses each of the other cards 310. Similarly, for example, in one embodiment, in which card 310₃ (i.e., DEBUG card) comprises the master circuit pack, DEBUG card 310₃ addresses each of the other cards 310 (including CTL card 310_{N}).

As described herein, FTC 130 comprises resistors 132 and capacitors 134 operable for terminating at least a portion of the signals on ORAB 120. Similarly, as described herein, STC 140 comprises resistors 142 and capacitors 144 operable for terminating at least a portion of the signals on ORAB 120. In one embodiment, as depicted in FIG. 3, in which the open-ring architecture bus is adapted for supporting boundary scan signaling, FTC 130 and STC 140 terminate signaling (illustratively, BSSs 150). In one embodiment, FTC 130 and STC 140 are implemented on a single module. In one further embodiment, the module comprising FTC 130 and STC 140 is adapted for interfacing with ORAB 120 (e.g., coupled to the rear side of the backplane).

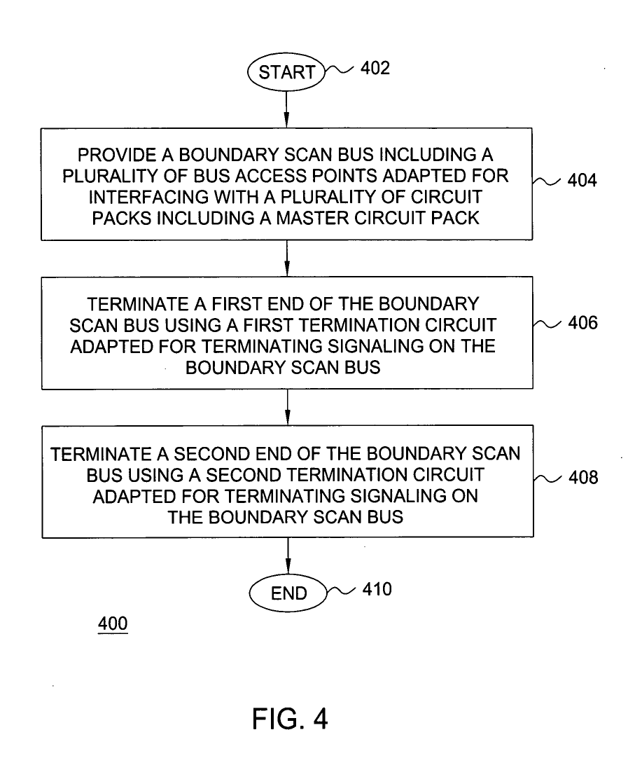

FIG. 4 depicts a flow diagram of a method according to one embodiment of the invention. Specifically, method 400 of FIG. 4 comprises a method for providing an open-ring architecture bus operable for providing multipoint access capabilities. Although depicted as being performing serially, those skilled in the art will appreciate that at least a portion of the steps of method 400 may be performed contemporaneously, or in a different order than presented in FIG. 4. The method 400 begins at step 402 and proceeds to step 404.

At step 404, a boundary scan bus is provided. In one embodiment, the boundary scan bus comprises a plurality of bus access points adapted for interfacing with a plurality of circuit packs including a master circuit pack. At step 406, a first end of the boundary scan bus is terminated using a first termination circuit. At step 408, a second end of the boundary scan bus is terminated using a second termination circuit. In one embodiment, the first termination circuit and second termination circuit are adapted for terminating signaling on the boundary scan bus in a manner enabling disposal of the master circuit pack at any of the plurality of bus access points. For example, as depicted and described with respect to FIG. 1, FTC 130 and STC 140 terminate signaling on ORAB 120. The method 400 then proceeds to step 410, where the method 400 ends.

In one embodiment, boundary scan master circuit pack multipoint access capability is provided using any slot on the front side of the backplane (illustratively, any of the slots 302). As such, using the open-ring architecture bus of the present invention, a signal may be applied to any access point of the open-ring architecture bus such that the signal propagates towards the ends of the open-ring architecture bus where the signals are terminated (i.e., by a first termination circuit and a second termination circuit). In other words, the open-ring architecture bus is implemented such that the architecture driving point (i.e., signaling source point) is variable (i.e., is not fixed at a particular access point).

As described herein, the open-ring architecture bus provides a master circuit pack with multipoint access capability. As such, in one embodiment, a master circuit pack is implemented as at least a portion of a controller card (i.e., CTL card) coupled to the front side of the backplane using an I/O slot. In one embodiment, a master circuit pack is implemented as at least a portion of an external host. For example, the master circuit pack may be implemented as a portion of a DEBUG card coupled to the front of the backplane using an I/O slot. In one embodiment, a master circuit pack is implemented as at least a portion of a circuit pack coupled to the rear side of the back plane (e.g., a circuit pack comprising FTC 130 and STC 140). In one embodiment, a master circuit pack is implemented as at least a portion of an internal circuit module (e.g., an internal module coupled to the backplane).

In one embodiment, the open-ring architecture bus is operable for supporting boundary scan testing capabilities. In one such embodiment, the master circuit pack multipoint access capability enables use of each input-output slot for controlling boundary scan testing. In one embodiment, boundary scan testing is controlled using an internal host. In one embodiment, boundary scan testing is controlled using an external host. As such, in one embodiment, a boundary scan master circuit pack is implemented as at least a portion of a controller card (i.e., CTL card) coupled to the front side of the backplane using an I/O slot, a DEBUG card coupled to the front of the backplane using an I/O slot and the like.

In one embodiment, the boundary scan master circuit pack is implemented as at least a portion of a circuit pack coupled to the rear side of the back plane. In one such embodiment, the boundary scan master circuit pack is implemented as a portion of a circuit pack comprising FTC 130 and STC 140. In one embodiment, a boundary scan master circuit pack is implemented as at least a portion of an internal circuit module coupled to the backplane. It should be noted that such configurations may be useful for implementing boundary scan testing capabilities for a fully-equipped shelf (i.e., no spare I/O slots associated with the front of the backplane are available).

In one embodiment, the open-ring architecture bus enables hierarchical boundary scan testing. In one embodiment, the open-ring architecture bus enables testing of individual circuit packs. For example, the open-ring architecture bus may be used for testing individual cards (e.g., an active CTL card, an inactive I/O card, and the like). In another embodiment, the open-ring architecture bus may be used for testing a hot-plug-in card before the card is activated for performing control functions (e.g., for a CTL card), carrying network traffic (e.g., for an I/O card), and the like. In one embodiment, the open-ring architecture bus enables testing of a plurality of cards. In one embodiment, the open-ring architecture bus enables testing of an entire shelf. In one embodiment, the open-ring architecture bus enables testing of an entire telecommunications system (e.g., a plurality of shelves).

Although primarily described herein with respect to boundary scan testing signaling, in one embodiment, the open-ring architecture bus may be used for performing various other signaling between circuit packs. In one embodiment, for example, the open-ring architecture bus may be used for performing other testing. In one embodiment, for example, the open-ring architecture bus may be used for downloading firmware, software, and the like to any device coupled to the open-ring architecture bus (e.g., individual circuit packs, groups of circuit packs, and the like). For example, in a running telecommunications system comprising an open-ring architecture bus, a card may be switched from in-service to out-of-service, from out-of-service to boundary scan mode, programmed with new firmware downloaded using the open-ring architecture bus, and switched from out-of-service to in-service, without having to remove the card from the shelf.

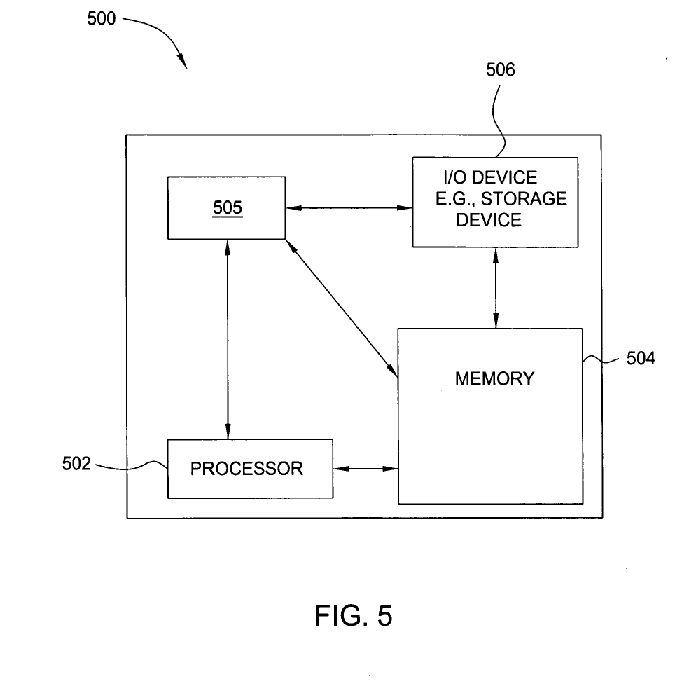

FIG. 5 depicts a high-level block diagram of a general purpose computer suitable for use in performing the functions described herein. As depicted in FIG. 5, system 500 comprises a processor element 502 (e.g., a CPU), a memory 504, e.g., random access memory (RAM) and/or read only memory (ROM), an open-ring architecture bus module 505, and various input/output devices 506 (e.g., storage devices, including but not limited to, a floppy drive, a hard disk drive or a compact disk drive, a receiver, a transmitter, an output port, and a user input device (such as a keyboard, a keypad, a mouse, and the like)).

It should be noted that the present invention may be implemented in software and/or in a combination of software and hardware, e.g., using application specific integrated circuits (ASIC), a general purpose computer or any other hardware equivalents. In one embodiment, the present open-ring architecture bus module or process 505 can be loaded into memory 504 and executed by processor 502 to implement the functions as discussed above. As such, open-ring architecture bus process 505 (including associated data structures) of the present invention can be stored on a computer readable medium or carrier, e.g., RAM memory, magnetic or optical drive or diskette and the like.

Although various embodiments which incorporate the teachings of the present invention have been shown and described in detail herein, those skilled in the art can readily devise many other varied embodiments that still incorporate these teachings.

What is claimed is:

1. An apparatus for providing multipoint bus access, comprising:
a boundary scan bus comprising a plurality of bus access points adapted for interfacing with a plurality of circuit packs including a master circuit pack;
a first termination circuit coupled to a first end of said boundary scan bus; and
a second termination circuit coupled to a second end of said boundary scan bus;
said first termination circuit and said second termination circuit adapted for terminating signaling on said boundary scan bus in a manner enabling disposal of said master circuit pack at any of said plurality of bus access points.

2. The apparatus of claim 1, further comprising:
a respective plurality of addressable scan port modules associated with said plurality of circuit packs, said addressable scan port modules operable for uniquely addressing said plurality of said circuit packs.

3. The apparatus of claim 1, wherein said master circuit pack is operable for controlling said signaling.

4. The apparatus of claim 1, wherein said signaling comprises signaling operable for performing a boundary scan test.

5. The apparatus of claim 1, wherein said signaling comprises signaling operable for performing at least one of a firmware upgrade and a software upgrade.

6. The apparatus of claim 1, wherein each of said plurality of circuit packs comprises a telecommunications module.

7. The apparatus of claim 6, wherein said master circuit pack comprises at least one of a control (CTL) card, a debug (DEBUG) card, and a card adapted for interfacing with a rear side of a backplane.

8. The apparatus of claim 1, wherein at least one of said first termination circuit and said second termination circuit comprises at least a portion of a telecommunications module.

9. The apparatus of claim 8, wherein said telecommunications module is adapted for interfacing with a backplane, said backplane associated with at least a portion of said plurality of circuit packs.

10. An method for providing multipoint bus access, comprising:
providing a boundary scan bus comprising a plurality of bus access points adapted for interfacing with a plurality of circuit packs including a master circuit pack;
terminating a first end of said boundary scan buss using a first termination circuit; and
terminating a second end of said boundary scan buss using a second termination circuit;
said first termination circuit and said second termination circuit adapted for terminating signaling on said boundary scan bus in a manner enabling disposal of said master circuit pack at any of said plurality of bus access points.

11. The method of claim 10, further comprising:
providing a respective plurality of addressable scan port modules associated with said plurality of circuit packs, said addressable scan port modules operable for uniquely addressing said plurality of said circuit packs.

12. The method of claim 10, wherein said master circuit pack is operable for controlling said signaling.

13. The method of claim 10, wherein said signaling comprises signaling operable for performing a boundary scan test.

14. The method of claim 10, wherein said signaling comprises signaling operable for performing at least one of a firmware upgrade and a software upgrade.

15. The method of claim 1, wherein each of said plurality of circuit packs comprises a telecommunications module.

16. The method of claim 16, wherein said master circuit pack comprises at least one of a control (CTL) card, a debug (DEBUG) card, and a card adapted for interfacing with a rear side of a backplane.

17. The method of claim 10, wherein at least one of said first termination circuit and said second termination circuit comprises at least a portion of a telecommunications module.

18. The method of claim 17, wherein said telecommunications module is adapted for interfacing with a backplane, said backplane associated with at least a portion of said plurality of circuit packs.

19. A system for providing multipoint bus access, comprising:
a plurality of circuit packs including a master circuit pack;
a boundary scan bus comprising a plurality of bus access points adapted for interfacing with said plurality of circuit packs;
a first termination circuit coupled to a first end of said boundary scan bus; and
a second termination circuit coupled to a second end of said boundary scan bus;
said first termination circuit and said second termination circuit adapted for terminating signaling on said boundary scan bus in a manner enabling disposal of said master circuit pack at any of said plurality of bus access points.

20. The system of claim 19, wherein said signaling comprises signaling operable for performing at least one of boundary scan testing, a firmware upgrade, and a software upgrade.
